(19) United States
(12) Patent Application Publication
(10) Pub. No.: US 2008/0006861 A1
(43) Pub. Date: Jan. 10, 2008

(54) Semiconductor device and manufacturing method thereof

(75) Inventor: Katsuhiro Sato, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 11/898,731

(22) Filed: Sep. 14, 2007

Related U.S. Application Data
(63) Continuation of application No. PCT/JP2005/004552, filed on Mar. 15, 2005.

(51) Int. Cl. H01L 29/94

(52) U.S. Cl. 257/295

(57) ABSTRACT

A semiconductor device is provided with a semiconductor substrate, a ferroelectric capacitor formed above the semiconductor substrate, and a film formed on the back face of the semiconductor substrate. In a method for manufacturing a semiconductor device, a ferroelectric capacitor is formed above a semiconductor substrate, and then the back face of the semiconductor substrate is polished. Thereafter, a film is formed on the back face of the semiconductor substrate.

### TECHNICAL FIELD

The present embodiment relates to a semiconductor device suitable for a nonvolatile memory having a ferroelectric capacitor, and a manufacturing method thereof.

### BACKGROUND ART

In a conventional ferroelectric memory having a ferroelectric capacitor, it has been required to avoid data retention failure and improve moisture resistance.

However, it is not at present possible to sufficiently avoid the data retention failure in the conventional structure. Moreover, when the thickness of the memory is further reduced in future, it might not be possible to sufficiently secure moisture resistance.

Patent Document 1: Japanese Patent Application Laid-Open No. 2003-229542

Patent Document 2: Japanese Patent Application Laid-Open No. 2003-297947

Patent Document 3: Japanese Patent Application Laid-Open No. 2001-210798

Patent Document 4: Japanese Patent Application Laid-Open No. 2001-111007

### SUMMARY

A semiconductor device according to the present embodiment is provided with a semiconductor substrate, a ferroelectric capacitor formed above the semiconductor substrate, and a film formed on the back face of the semiconductor substrate.

In a method for manufacturing a semiconductor device according to the present embodiment, a ferroelectric capacitor is formed above a semiconductor substrate, and then the back face of the semiconductor substrate is polished. Thereafter, a film is formed on the back face of the semiconductor substrate.

### BRIEF DESCRIPTION OF THE DRAWINGS

FIG. 1 is a circuit diagram showing a configuration of a memory cell array of a ferroelectric memory (semiconductor device) manufactured by a method according to the present embodiment;

FIG. 2A is a cross-sectional view showing a method for manufacturing a ferroelectric memory in order of steps according to the embodiment;

FIG. 2B is a cross-sectional view showing, subsequently to FIG. 2A, a method for manufacturing a ferroelectric memory in order of steps according to the embodiment;

FIG. 2C is a cross-sectional view showing, subsequently to FIG. 2B, a method for manufacturing a ferroelectric memory in order of steps according to the embodiment;

FIG. 2D is a cross-sectional view showing, subsequently to FIG. 2C, a method for manufacturing a ferroelectric memory in order of steps according to the embodiment;

FIG. 2E is a cross-sectional view showing, subsequently to FIG. 2D, a method for manufacturing a ferroelectric memory in order of steps according to the embodiment;

FIG. 3 is a view showing a change in warpage level of a semiconductor substrate;

FIG. 4 is a graph showing results of measurement of switching charge density;

FIG. 5A is a cross-sectional view showing a structure of a sample; and

FIG. 5B is a cross-sectional view showing a structure of another sample.

### DETAILED DESCRIPTION OF THE PREFERRED EMBODIMENTS

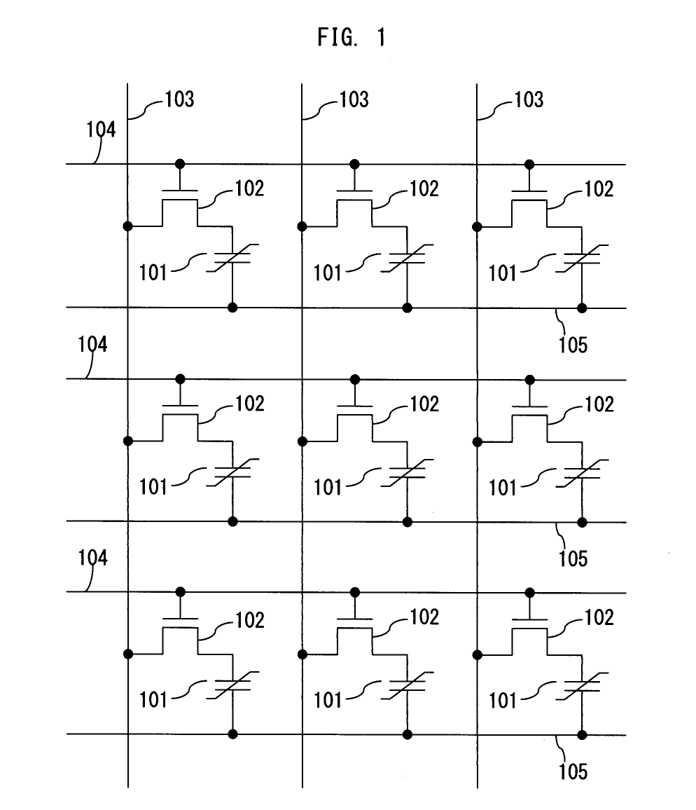

In the following, an embodiment is specifically described with reference to attached drawings. FIG. 1 is a circuit diagram showing a configuration of a memory cell array of a ferroelectric memory (semiconductor device) manufactured by a method according to the embodiment.

This memory cell array is provided with a plurality of bit lines 103 extending in a direction, and a plurality of word lines 104 and plate lines 105 extending in a direction perpendicular to the direction in which the bit lines 103 extend. Further, a plurality of memory cells of a ferroelectric memory according to the present embodiment are arranged in array form so as to be matched to grids consisting of the bit lines 103, the word lines 104 and the plate lines 105. Each of the memory cells is provided with a ferroelectric capacitor (storage section) 101 and an MOS transistor (switching section) 102.

A gate of the MOS transistor 102 is connected to the word line 104. Further, one of a source/drain of the MOS transistor 102 is connected to the bit line 103, and the other of the source/drain is connected to one of electrodes of the ferroelectric capacitor 101. The other electrode of the ferroelectric capacitor 101 is connected to the plate line 105. It is to be noted that each of the word lines 104 and the plate lines 105 are shared by a plurality of MOS transistors 102 aligned in the same direction as the direction in which those lines extend. Similarly, each of the bit lines 103 is shard by a plurality of MOS transistors 102 aligned in the same direction as the direction in which the line extends. The direction in which the word lines 104 and the plate lines 105 extend and the direction in which the bit lines 103 extend may be respectively called a row direction and a column direction. Arrangement of the bit lines 103, the word lines 104 and the plate lines 105 is not limited to the foregoing arrangement.

In the memory cell array of the ferroelectric memory as thus configured, data is stored according to a polarized state of the ferroelectric film provided in the ferroelectric capacitor 101.

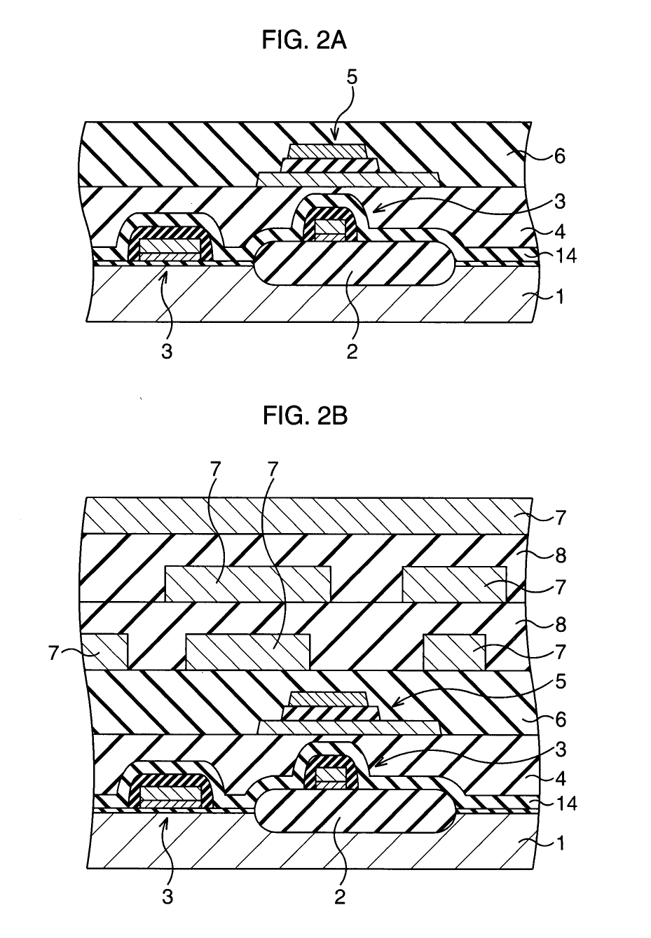

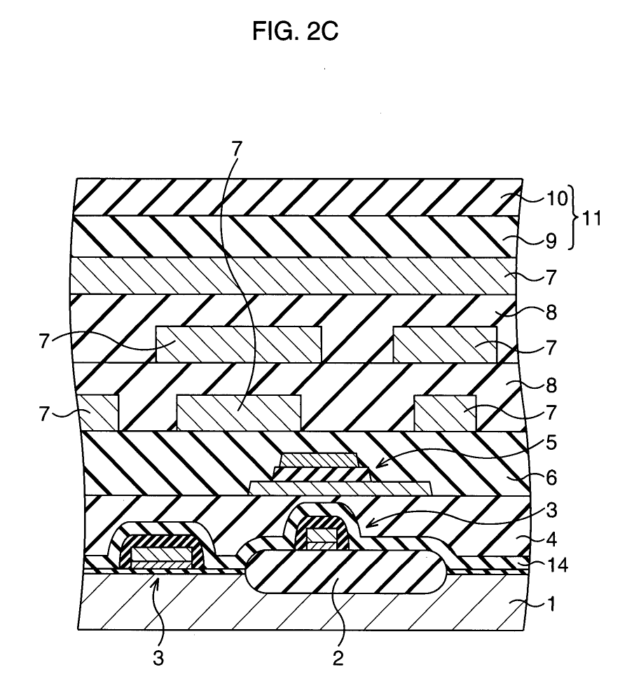

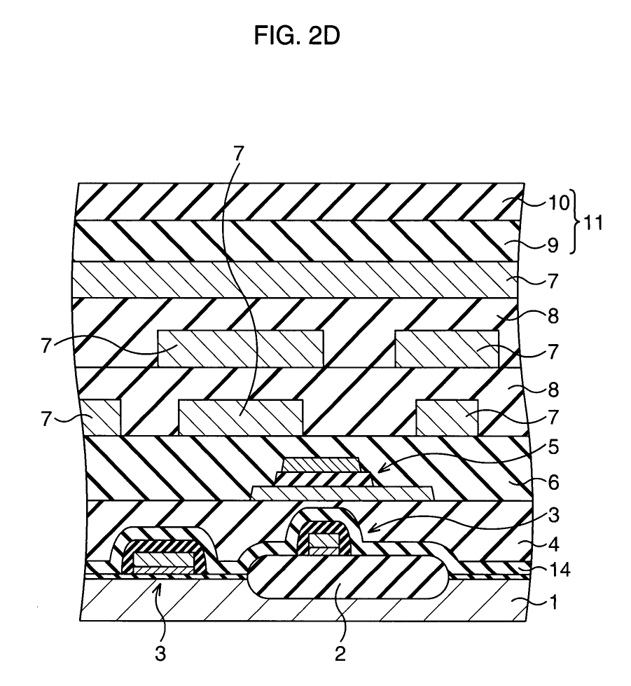

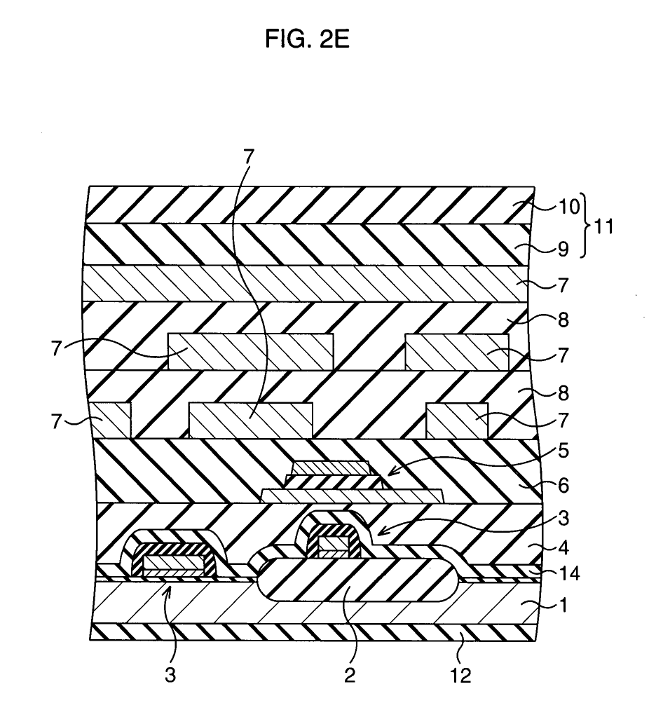

Next, the embodiment is described. In this description, a cross-sectional structure of the ferroelectric memory is described along with a manufacturing method thereof, for the sake of convenience. FIGS. 2A to 2E are cross-sectional views showing a method for manufacturing a ferroelectric memory (semiconductor device) in order of steps according to the embodiment.

In the present embodiment, first, as shown in FIG. 2A, an element isolation film 2 partitioning element active regions is formed by, for example, LOCOS (local oxidation of silicon) on the front face of the semiconductor substrate 1 such as a Si substrate. Next, a plurality of transistors 3 are formed within the element active regions partitioned by the element isolation film 2 and on the element isolation film 2. Part of the plurality of transistors 3 correspond to the MOS transistors 102 in FIG. 1. Subsequently, a silicon oxynitride film 14 is formed all over the face so as to cover a MOSFET, and a silicon oxide film 4 is further formed as an interlayer insulating film all over the face.

The silicon oxynitride film 14 is formed for the purpose of preventing hydrogen deterioration in a gate insulating film and the like in formation of the silicon oxide film 4. As the silicon oxide film 4, for example, a TEOS (tetraethylorthosilicate) film having a thickness of about 700 nm is formed by CVD (chemical vapor deposition).

Thereafter, on the silicon oxide film 4, a ferroelectric capacitor 5 having a bottom electrode, a ferroelectric film such as a PZT film, and a top electrode is formed. This ferroelectric capacitor 5 corresponds to the ferroelectric capacitor 101 in FIG. 1. Subsequently, an interlayer insulating film 6 covering the ferroelectric capacitor 5 is formed.

Next, as shown in FIG. 2B, multilayer wiring 7 and interlayer insulating films 8 are formed on the interlayer insulating film 6. Then, as shown in FIG. 2C, a Si oxide film 9 and a Si nitride film 10 are sequentially formed all over the face, so as to form a cover film 11. Thereafter, an opening (not shown) for a pad is formed in the cover film 11.

Subsequently, as shown in FIG. 2D, the back face of the semiconductor substrate 1 is polished. This aims to adjust the thickness and remove a substance having adhered to the back face.

Thereafter, as shown in FIG. 2E, an alumina film 12 having a thickness of about 20 nm to 50 nm, for example, is formed on the back face of the semiconductor substrate 1 by sputtering or the like. At this time, adjustment of a formation method and the thickness of the alumina film 12 allows adjustment of a warpage level of the semiconductor substrate 1. In numerous cases, a favorable characteristic is easier to obtain and data retention failure is less prone to occurring when the front face, on which semiconductor elements are formed, is warped so as to be concave than when the front face is warped so as to be convex.

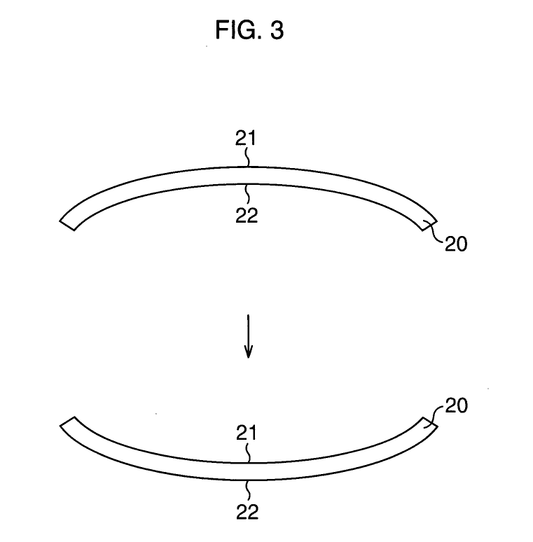

According to the present embodiment as thus described, adjustment of the formation method, the thickness, etc. of the alumina film 12 allows adjustment of the warpage level of the semiconductor substrate 1, thereby making the data retention failure less prone to occurring. Namely, as shown in FIG. 3, when the front face 21 of the semiconductor substrate 1 (semiconductor wafer 20), on which the transistors 3 and the like are formed, is convex and the back face 22 is concave after polishing of the back face, formation of the alumina film 12 allows adjustment of the warpage level such that the front face 21 becomes concave and the back face 22 becomes convex. Further, entry of moisture and the like from the back face side of the semiconductor substrate 1 can be suppressed by the presence of the alumina film 12. Therefore, even when reduction in thickness of the semiconductor substrate 1 is requested, it is possible to suppress deterioration in moisture resistance associated with the reduction.

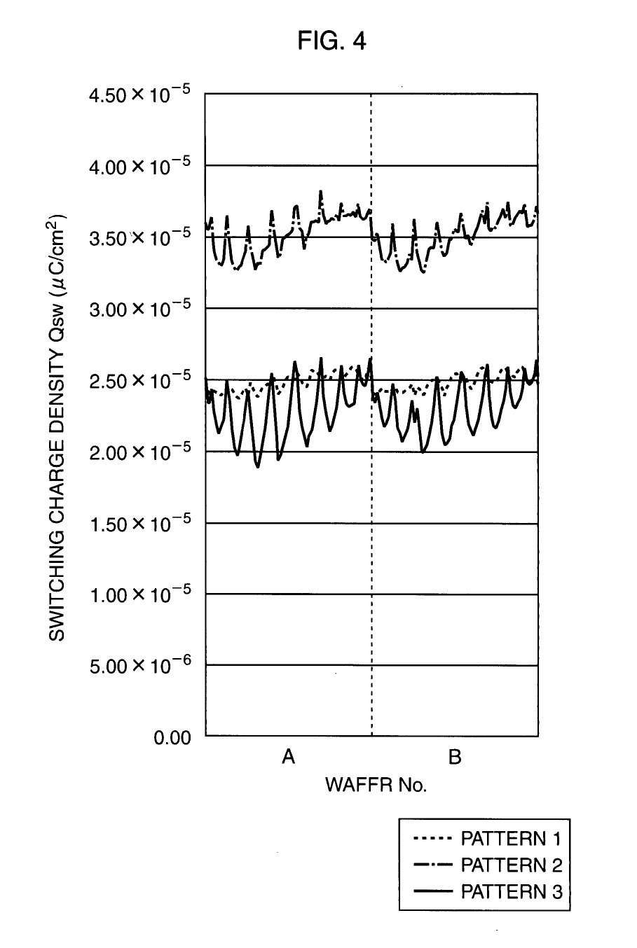

Next, results of a test conducted by the present inventor are described. For this test, three kinds of patterns of ferroelectric capacitors were set, and two kinds of samples were prepared per pattern. In one sample (wafer No. A), no alumina film was formed on the back face and the front face was formed to be convex. In the other sample (wafer No. B), as opposed to the one sample, an alumina film was formed on the back face and the front face was formed to be concave. A switching charge density Q_{SW} on each of these samples was then measured. Measurement results are shown in FIG. 4. It should be to be noted that a pattern 1 was arrangement of a ferroelectric capacitor of square (in planar shape) having a side length of 50 μm. A pattern 2 was arrayed arrangement of a plurality of ferroelectric capacitors of square (in planar shape) having a side length of 1.2 μm. A pattern 3 was staggered arrangement of a plurality of ferroelectric capacitors of square (in planar shape) having a side length of 1.2 μm.

As shown in FIG. 4, a variation was smaller in the case of using wafer No. B according to the embodiment than the wafer No. A.

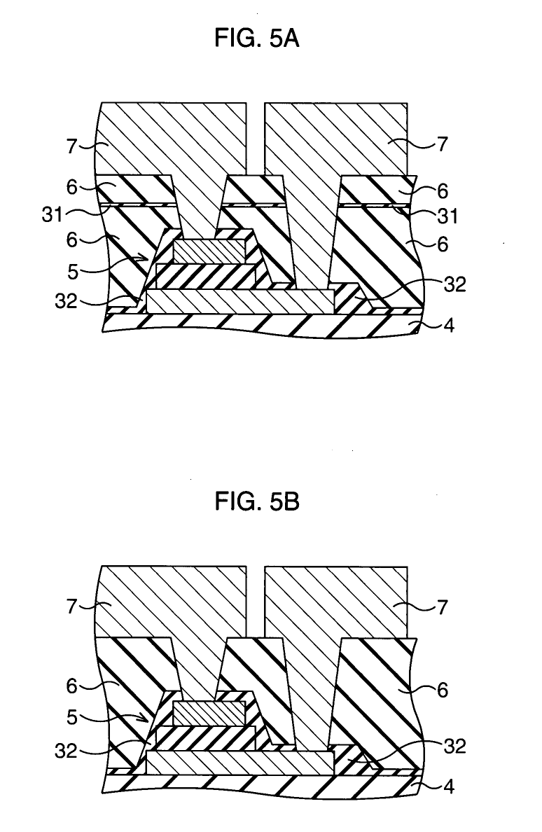

The present inventor also conducted a test concerning the relation between the alumina film and the moisture resistance. Two kinds of samples were prepared for this test. One sample included an alumina film 32 covering the ferroelectric capacitor 5 and an alumina film 31 placed in the interlayer insulating film 6, as shown in FIG. 5A. The other sample included the alumina film 32 but did not include the alumina film 31, as shown in FIG. 5B. A test concerning reliability was then conducted on these samples.

In this test concerning reliability, two kinds of environmental conditions, such as air pressure, temperature and moisture, were set, and the lengths of the time for which the above two kinds of samples could normally operate were checked under each of the conditions.

Under a first condition, as for the sample (with the alumina film 31) shown in FIG. 5A, all of five prepared samples normally operated after both the elapsed time of 168 and 672 hours. On the other hand, as for the sample (without the alumina film 31) shown in FIG. 5B, one out of five prepared samples did not normally operate in a test after the elapsed time of 168 hours. Further, three samples did not normally operate in a test after the elapsed time of 672 hours.

Under a second condition, as for the sample (with the alumina film 31) shown in FIG. 5A, all of 22 prepared samples normally operated after both the elapsed time of 168 and 504 hours. Further, all of seven prepared samples normally operated after the elapsed time of 840 hours. On the other hand, as for the sample (without the alumina film 31) shown in FIG. 5B, three out of 38 prepared samples did not normally operate in a test after the elapsed time of 168 hours. Further, 15 prepared samples did not normally operate in a test after the elapsed time of 504 hours.

It was confirmed from these test results that moisture resistance had been increased by the presence of the alumina film 31. It should to be noted that, although the alumina film 31 was formed on the front face side of the semiconductor substrate, an alumina film formed on the back face is thought to similarly contribute to improvement in moisture resistance.

Next, results of a test conducted on the relation between the kind, thickness and the like of the film formed on the back face of the semiconductor substrate and the change in warpage level thereof.

In this test, after formation of the film on the back face of the semiconductor substrate, stress working on the semiconductor substrate was optically measured. The results are shown in Table 1. It should be to be noted that the surface of the semiconductor substrate became convex when a value of stress in Table 1 was negative, and the surface became concave when the value was positive.

TABLE 1

| | Film thickness | | |
|---|---|---|---|
| Film kind | (nm) | Stress | Note |
| Si oxynitride film | 1500 | −2.0 ± 1.0 × | |
| | | 10⁹ dyne/cm² | |
| Si oxynitride film | 2600 | −1.5 ± 0.5 × | |
| | | 10⁹ dyne/cm² | |
| Si oxynitride film | 100 | −1.5 ± 0.5 × | |
| | | 10⁹ dyne/cm² | |
| Si nitride film | 350 | −2.0 ± 1.0 × | |
| | | 10⁹ dyne/cm² | |
| Al film | 500 | +5.0 ± 0.5 × | |
| | | 10⁹ dyne/cm² | |
| Alumina film | 20 | −1.8 ± 1.0 × | Not |
| | | 10⁹ dyne/cm² | annealed |
| Alumina film | 20 | +8.5 ± 1.0 × | Annealed |
| | | 10⁸ dyne/cm² | |
| Alumina film | 50 | +5.4 ± 0.4 × | Not |
| | | 10⁹ dyne/cm² | annealed |

As shown in Table 1, when the silicon oxynitride film or the silicon nitride film was formed on the back face of the semiconductor substrate, a value of stress was negative regardless of the film thickness. Namely, the front face became convex, being warped into chevron shape. On the other hand, when the Al film was formed, a value of stress was positive. Namely, the front surface became concave, being warped into bowl shape.

Further, when the alumina film was formed, the direction in which the front face was warped was different depending upon the film thickness and whether or not annealing had been performed. For example, when the alumina films with the same thickness (20 nm) were formed, the stress value was negative and the front face became convex (chevron shape) in the sample with the alumina film not annealed after its formation, whereas the stress value was positive and the front face became concave (bowl shape) in the sample with the alumina film annealed after its formation. Further, even when annealing was not performed, the stress value was negative and the front face became convex (chevron shape) in the sample with a film thickness of 20 nm, whereas the stress value was positive and the front face became concave (bowl shape) in the sample with a film thickness of 50 nm.

In the manner described above, it is possible to adjust the warpage level according to the kind, the thickness, etc. of a film to be formed on the back face of the semiconductor substrate. As thus described, it is said that in numerous cases, a more favorable characteristic can be obtained when the front face of the semiconductor substrate is concave and warped in bowl shape. However, even when a situation occurs where warping the front face into chevron shape is more preferable, it is possible to deal with such a situation by appropriately adjusting the kind, the thickness, etc. of the film.

In addition, as the ferroelectric film there may be used a PZT (PbZr₁₋ₓTiₓO₃) film, a compound film having a perovskite structure such as a film obtained by adding trace quantities of La, Ca, Sr, Si or the like to the PZT film, or a compound film having a Bi layered structure such as a (SrBi₂TaₓNb₁₋ₓO₉) film or a Bi₄Ti₂O₁₂ film. Further, the method for forming the ferroelectric film is not particularly limited, but the ferroelectric film can be formed by sol-gel processing, sputtering, MOCVD, or the like.

### INDUSTRIAL APPLICABILITY

As specifically described above, according to the present embodiment, it is possible to adjust a warpage level of a semiconductor substrate by a film formed on the back face thereof. Consequently, data retention failure can be avoided with more reliability.

What is claimed is:

1. A semiconductor device comprising:
a semiconductor substrate;
a ferroelectric capacitor formed above said semiconductor substrate; and
a film formed on a back face of said semiconductor substrate.

2. The semiconductor device according to claim 1, wherein said film is one selected from a group consisting of an alumina film, a Si oxynitride film, a Si nitride film, and an Al film.

3. The semiconductor device according to claim 1, wherein said film is an alumina film having a thickness of 20 nm to 50 nm.

4. The semiconductor device according to claim 1, wherein said semiconductor substrate is warped so as to have a concave front face.

5. The semiconductor device according to claim 1, further comprising an alumina film formed above said ferroelectric capacitor.

6. A method for manufacturing a semiconductor device comprising the steps of:
forming a ferroelectric capacitor above a semiconductor substrate;
polishing a back face of said semiconductor substrate; and
forming a film on said back face of said semiconductor substrate.

7. The method for manufacturing a semiconductor device according to claim 6, wherein one selected from a group consisting of an alumina film, a Si oxynitride film, a Si nitride film and an Al film is formed as said film.

8. The method for manufacturing a semiconductor device according to claim 6, wherein an alumina film having a thickness of 20 nm to 50 nm is formed as said film.

9. The method for manufacturing a semiconductor device according to claim 6, wherein said film is formed to warp said semiconductor substrate so as to have a concave front face.

10. The method for manufacturing a semiconductor device according to claim 6, further comprising the step of forming an alumina film above said ferroelectric capacitor between the step of forming said ferroelectric capacitor and the step of polishing said back face of said semiconductor substrate.

11. The method for manufacturing a semiconductor device according to claim 6, wherein said film is formed by sputtering.

12. The method for manufacturing a semiconductor device according to claim 6, wherein said film is formed to warp said semiconductor substrate so as to have a convex front face.

13. The method for manufacturing a semiconductor device according to claim 6, further comprising the step of performing annealing treatment after the step of forming said film.
